(19) United States
(12) Patent Application Publication
(10) Pub. No.: US 2010/0085078 A1
(43) Pub. Date: Apr. 8, 2010

(54) Digital Logic Voltage Level Shifter

(75) Inventor: Rob Chapman, Edmonton (CA)

Correspondence Address: HENNEMAN & ASSOCIATES, PLC, 70 N. MAIN ST., THREE RIVERS, MI, 49093, US

(73) Assignee: VNS PORTFOLIO LLC, Cupertino, CA (US)

(21) Appl. No.: 12/247,000

(22) Filed: Oct. 7, 2008

(51) Int. Cl. H03K 19/0185

(52) U.S. Cl. 326/63

(57) ABSTRACT

A digital logic level shifter having three stages. An initial stage includes a conventional 4-terminal bridge-type inverter circuit. A middle stage includes a 5-terminal first logic reversing circuit that has two middle stage inputs that are not connected in common. And a final stage includes a 5-terminal second logic reversing circuit that has two final stage inputs that are not connected in common.

### BACKGROUND OF THE INVENTION

1. Technical Field

The present invention relates generally to electronic digital logic circuitry, and more particularly to supply voltage level shifting (i.e., interface between devices of a same logic family with different operating voltage levels).

2. Background Art

In modern electronic systems it is often necessary to connect domains at different voltage levels. The examples herein use the common complimentary metal-oxide semiconductor (CMOS) digital logic integrated circuit (IC), but skilled artisans will appreciate that the principles presented here extend beyond CMOS and the simple logic circuits used for the sake of this discussion.

Example of connecting different voltage domains today can be seen in many modern microprocessor ICs. These typically contain at least one processor core that uses one voltage yet there is also other circuitry, either inside or outside the IC, that uses a different voltage. Various reasons can motivate this arrangement, for instance, to operate the core at a low supply voltage (e.g., 1.8 V) to reduce power consumption and increasing signal switching times, yet to operate the other circuits at a higher voltage (e.g., 3.3V) for greater electronic noise tolerance. Unfortunately, converting digital outputs in this manner to higher voltage levels presents a design problem.

FIGS. 1a-1c (prior art) depict the portions and the entirety of a simple known digital level shifter 10. FIG. 1a shows a common inverter 12 as a logic element, FIG. 1b is a schematic diagram of a typical CMOS circuit inside the inverter 12, and FIG. 1c is a schematic diagram of the digital level shifter 10 that includes two of the inverters 12.

FIG. 1a is self-explanatory to those knowledgably in this art, so we turn directly now to FIG. 1b. The inverter 12 here includes an NMOS device 14 paired with a PMOS device 16 in a bridge configuration (i.e., a four terminal network with a two supply terminals opposite each other and a load input terminal and a load output terminal opposite each other). This conventional bridge-type inverter 12 is supplied with Vdd and ground, receives a signal having a digital logic state at an input node 18, and provides a signal having the opposite digital logic state at an output pad 20.

In operation the signal at the input node 18 causes the NMOS device 14 and the PMOS device 16 to turn off or on to drive the output pad 20 to ground or to the output voltage. To turn off the NMOS device 14 its gate is brought to ground, and to turn on the NMOS device 14 its gate is brought above a threshold voltage, Vth, which is a fraction of the operating voltage, Vdd. The PMOS device 16 is turned off by having the voltage between its source and gate be 0 volts, which is done by setting its gate to the same voltage as its source, which is usually the power rail voltage. The PMOS device 16 is turned on by setting the voltage at its gate to 0 volts. (It should be recalled that CMOS is capable of driving its outputs rail to rail, which simplifies the circuit and the example here.)

The problem with this is that the inverter 12 has the gates of both the NMOS device 14 and the PMOS device 16 tied together and the inverter 12 is typically driven by an output from a prior circuit. This puts the onus on the prior circuit to achieve the rail to rail voltages needed to switch the inverter between digital values. Since the NMOS device 14 can be driven fully on and off by an “up-stream” inverter, this does not present the problem. Rather, the problem is driving the PMOS device 16 fully off. The PMOS device 16 can be fully driven on by an up-stream lower voltage inverter, but that lower voltage up-stream inverter cannot achieve the required higher gate voltage needed to fully turn the PMOS device 16 off. This leaves the PMOS device 16 in a conducting state where a leakage current flows through both the PMOS device 16 and the NMOS device 14, resulting in increased power consumption.

FIG. 1c shows how the digital level shifter 10 interfaces between two voltage domains by using two inverters 12, a first inverter 12a and a second inverter 12b. The first inverter 12a is supplied with VddL and ground and particularly has an input node 18a, whereas the second inverter 12b is supplied with VddH and ground and particularly has an output pad 20b. The respective NMOS and PMOS devices are referenced here as p1 and n1, and p2 and n2.

The n1/p1 inverter 12a can only drive the gates of the n2/p2 inverter 12b to 0V or VddL. To fully turn off p2, its gate must be driven to VddH. If VddL and VddH are equal, this arrangement works. But if VddL is 1.8V and VddH is 3.3V, for instance, the gate of p2 will only reach 1.8V, leaving a voltage difference of 1.5V across the gate to source and keeping p2 turned on. Since n2 is also turned on, current will flow through p2 and n2 to ground, wasting power and raising Vout at the output pad 20b slightly above 0 volts due to the on resistance of n2.

It accordingly follows that the prior art digital level shifter 10 is functional but has disadvantages that become increasingly significant as the voltages at its input node 18a and its output pad 20b differ.

FIG. 2 (prior art) is a schematic diagram of an improved digital voltage level shifter 50, one in accord with U.S. Pat. No. 6,429,683 by Miller, et al. The voltage level shifter 50 here includes three conventional bridge-type inverters 52a-b, a feedback unit 54, and a pull-up device 56. In operation, an input signal drives the first inverter 52a and the second inverter 52b simultaneously. The first inverter 52a transforms the input signal into a logically inverted form with a high-voltage swing, while the second inverter 52b transforms the input signal into a logically inverted form with a relatively lower voltage swing. The third inverter 52c then inverts the high-voltage-swing signal so that an output signal having a proper high-voltage-swing is produced. Both the high-voltage-swing signals and the low-voltage-swing signals are used to drive the feedback unit 54, which, in turn, produces a feedback signal. This feedback signal controls the pull-up device 56, which is responsible for delivering power to the first inverter 52a. When necessary, the pull-up device 56 shuts off power to the first inverter 52a so that the voltage level shifter 50 draws no static current.

In particular, it should be noted above that the inverters 52a-b here comprise six field effect transistors (FETs), the feedback unit 54 comprises two more FETs, and the pull-up device 56 comprises one more FET, for a total of nine in this voltage level shifter 50. With reference briefly back to FIG. 1c, it can be noted that the digital level shifter 10 there comprises only four FETs. This is a significant difference in the count of transistors used to accomplish the same basic function, and in devices where large numbers of digital voltage level shifters are needed this imposes various burdens (e.g., footprint, design complexity, etc.).

It follows that many electronic systems will benefit from a digital voltage level shifter that has fewer components than the shifter 50 yet that does not suffer from the disadvantages of the shifter 10.

### BRIEF SUMMARY OF THE INVENTION

Accordingly, it is an object of the present invention to provide an improved digital logic voltage level shifter.

Briefly, one preferred embodiment of the present invention is a digital logic level shifter having three stages. An initial stage includes a conventional 4-terminal bridge-type inverter circuit. A middle stage includes a 5-terminal first logic reversing circuit that has two middle stage inputs that are not connected in common. And a final stage includes a 5-terminal second logic reversing circuit that has two final stage inputs that are not connected in common.

Briefly, another preferred embodiment of the present invention is a method for performing a voltage level shift on a digital input signal having logic states represented by a ground voltage level or a first voltage level, to produce a digital output signal having logic states represented by the ground voltage level or a second voltage level. The input signal is inverted into an initial stage output having opposite logic state, as represented by either the ground voltage level or the first voltage level. The input signal and the output signal are received into a middle stage, wherein the input signal and the output signal have corresponding logic states, and a middle stage is produced output that has opposite logic state, as represented by either the ground voltage level or the second voltage level. And the middle stage output and the initial stage output are received into a final stage, wherein the middle stage output and the initial stage output have corresponding logic states, and the output signal is produced having opposite logic state, as represented by either the ground voltage level or the second voltage level.

These and other objects and advantages of the present invention will become clear to those skilled in the art in view of the description of the best presently known mode of carrying out the invention and the industrial applicability of the preferred embodiment as described herein and as illustrated in the figures of the drawings.

### BRIEF DESCRIPTION OF THE SEVERAL VIEWS OF THE DRAWING(S)

The purposes and advantages of the present invention will be apparent from the following detailed description in conjunction with the appended figures of drawings in which:

FIGS. 1a-1c (prior art) depict the portions and the entirety of a simple known digital level shifter, wherein FIG. 1a shows a common inverter as a logic element, FIG. 1b is a schematic diagram of a typical CMOS circuit inside the inverter, and FIG. 1c is a schematic diagram of the digital level shifter that includes two of the inverters;

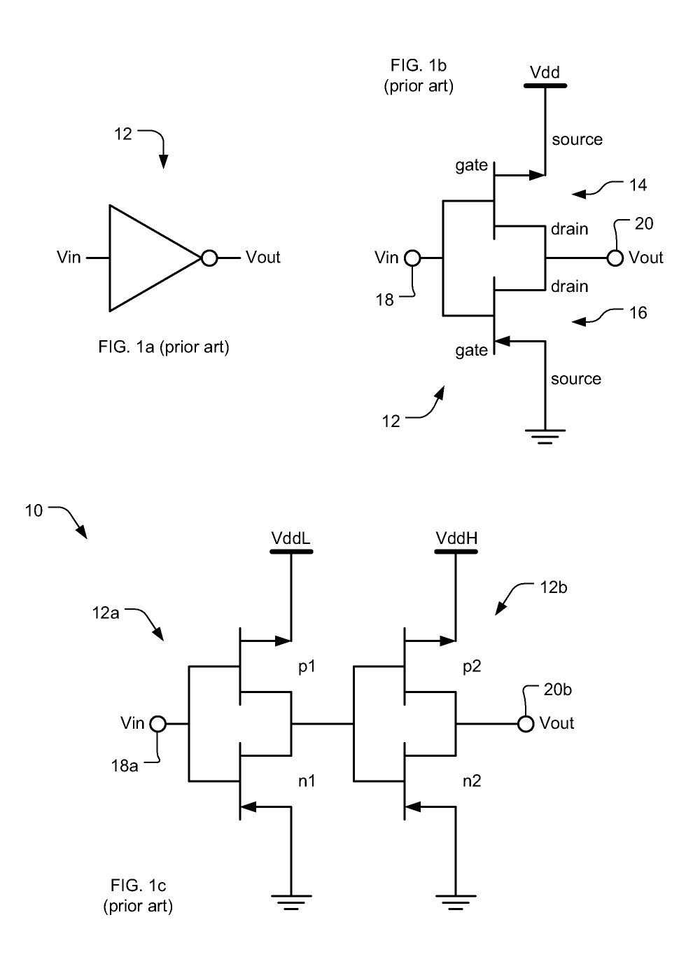

FIG. 2 (prior art) is a schematic diagram of an improved digital voltage level shifter; and

FIG. 3 is a schematic diagram of a digital voltage level shifter that is in accord with the present invention.

In the various figures of the drawings, like references are used to denote like or similar elements or steps.

### DETAILED DESCRIPTION OF THE INVENTION

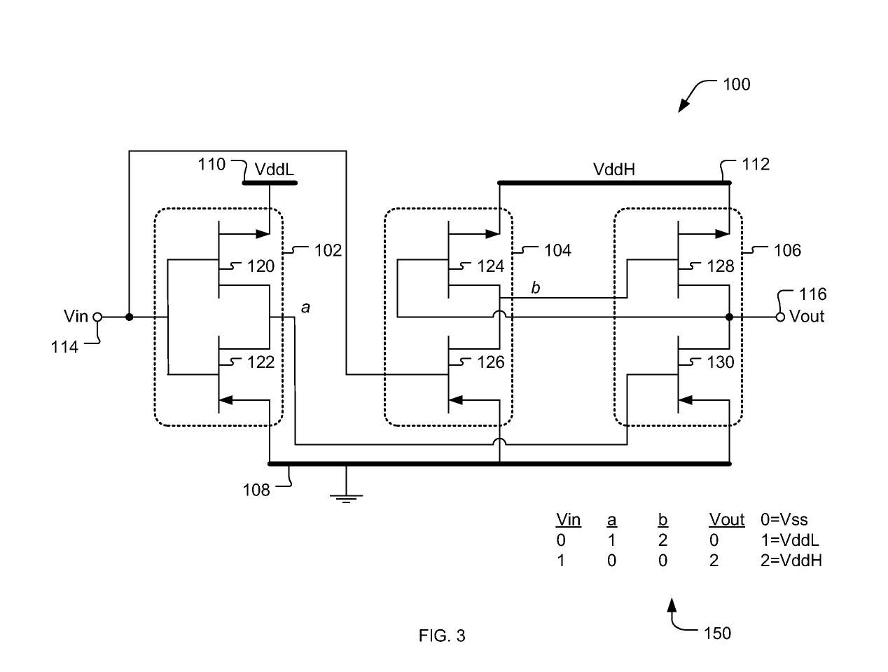

A preferred embodiment of the present invention is a digital logic voltage level shifter. As illustrated in the various drawings herein, and particularly in the view of FIG. 3, preferred embodiments of the invention are depicted by the general reference character 100.

FIG. 3 is a schematic diagram of a digital voltage level shifter 100 that is in accord with the present invention. Briefly, the shifter 100 has three major stages: an initial stage 102 that performs an inverting function, a middle stage 104 that performs a logic reversing function, and a final stage 106 that also performs a logic reversing function. Overall, the shifter 100 is a five terminal circuit, having a ground terminal 108, a low supply voltage terminal 110 (VddL), a high voltage supply terminal 112 (VddH), an input terminal 114 (Vin), and an output terminal 116 (Vout).

The initial stage 102 includes a PMOS transistor 120 and an NMOS transistor 122 that are connected to form a conventional bridge-type inverter. The source of the PMOS transistor 120 is connected to the low supply voltage terminal 110 (VddL) and the source of the NMOS transistor 122 is connected to the ground terminal 108. The gates of the PMOS transistor 120 and the NMOS transistor 122 are tied in common and connected to the input terminal 114 (Vin). And the drains of the PMOS transistor 120 and the NMOS transistor 122 are tied in common (and connected to the final stage 106 as described presently). As such, the initial stage 102 is a four-connection sub-circuit, having two supply connections, an input connection, and an output connection.

The middle stage 104 includes a PMOS transistor 124 and an NMOS transistor 126 but the gates of these are not made common. Instead, the gate of the PMOS transistor 124 is connected to the output terminal 116 (Vout) of the shifter 100 to receive feedback and the gate of the NMOS transistor 126 is connected to the input terminal 114 (Vin). The drains of the PMOS transistor 124 and the NMOS transistor 126 are tied in common (and connected to the final stage 106 as described presently). The middle stage 104 thus is a five-connection sub-circuit, having two supply connections, two input connections, and an output connection.

The final stage 106 includes a PMOS transistor 128 and an NMOS transistor 130. Similar to the middle stage 104, the gates of the transistors here in the final stage 106 are not made common. Instead, the gate of the PMOS transistor 128 is connected to the “output” of the middle stage 104 by connecting it to the common drains of the transistors 124, 126 there. The gate of the NMOS transistor 130 here is connected to the “output” of the initial stage 102, by connecting it to the common drains of the transistors 120, 122 there. And the drains of the PMOS transistor 128 and the NMOS transistor 130 here are tied in common and connected to the output terminal 116 (Vout) of the shifter 100. The final stage 106 thus also is a five-connection sub-circuit, having two supply connections, two input connections, and an output connection.

FIG. 3 additionally includes a table 150 that lists the values for Vin, Vout, and intermediate voltages at a node “a” and a node “b,” wherein node “a” is at the output connection of the initial stage 102 and node “b” is at the output connection of the middle stage 104. Table 150 summarizes how the digital voltage level shifter 100 functions in the desired manner.

The NMOS transistor 130 in the final stage 106 is driven by the output of the initial stage 102. The PMOS transistor 128 of the final stage 106 is driven by the output of the middle stage 104. And as noted above, the middle and final stages 104, 106 do not have the gates of their transistors connected, thus permitting these to be driven by different circuits to achieve rail to rail operation.

The input voltage Vin is inverted at node “a” and the two signal levels that can be present in Vin alternately drive the NMOS transistor 130 in the final stage 106 or the NMOS transistor 126 in the middle stage 104. This drives node “b” and Vout to the ground rail.

The gate of the PMOS transistor 124 in the middle stage 104 is driven by feedback from the output (Vout). When the NMOS transistor 130 in the final stage 106 is pulled low, by node “a” going high (from Vin going low), feeding back the output (Vout) drives the PMOS transistor 124 in the middle stage 104 low, turning it on and driving node “b” to VddH. When node “b” is driven to VddH, this turns off the PMOS transistor 128 in the final stage 106.

When Vin goes high, node “a” goes low. This turns off the NMOS transistor 130 in the final stage 106 and turns on the NMOS transistor 126 in the middle stage 104, driving node “b” low, turning on the PMOS transistor 128 in the final stage 106 and bringing Vout up to VddH. This drives the gate of the PMOS transistor 124 in the middle stage 104 to the rail, which turns it off.

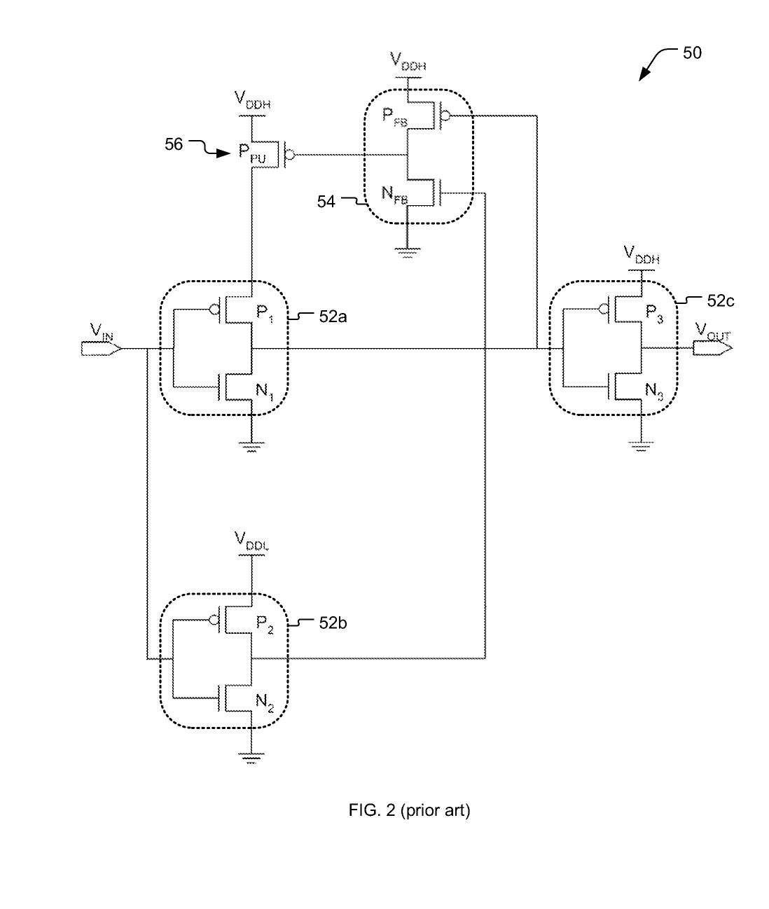

Summarizing and with reference to FIG. 3 and again to FIG. 2, it can be appreciated that the inventive digital voltage level shifter 100 uses only six FETs to accomplish the same voltage level shift that the prior art digital voltage level shifter 50 requires nine FETs to accomplish. These two circuits are similar in that they accomplish the same function but through different mechanisms.

Some additional considerations of digital voltage level shifter 100 are that the fall time of the output signal is longer than the rise time, due to the feedback circuit (and since the prior art shifter 50 also has a feedback circuit thus, often the two approaches do not differ by much). This can be compensated for by tuning of the size of the transistors. Additionally, since fall time is greatly affected by load capacitance, this can also slow the feedback from the output terminal 116 of the shifter 100. If this is an issue, however, an extra inverter stage can be added to drive the output terminal. The inventive solution then uses eight FETs, but this is still a significant improvement.

While various embodiments have been described above, it should be understood that they have been presented by way of example only, and that the breadth and scope of the invention should not be limited by any of the above described exemplary embodiments, but should instead be defined only in accordance with the following claims and their equivalents.

THIS CORRESPONDENCE CHART IS FOR EASE OF UNDERSTANDING AND INFORMATIONAL PURPOSES ONLY, AND DOES NOT FORM A PART OF THE FORMAL PATENT APPLICATION.
10 shifter
12, 12a-b inverters
14 NMOS device
16 PMOS device
18 input node
18a input node
20 output pad
20b output pad
50 shifter
52a-c inverters
54 feedback unit
56 pull-up device
100 shifter
102 initial stage
104 middle stage
106 final stage
108 ground terminal
110 low supply voltage terminal
112 high voltage supply terminal
114 input terminal
116 output terminal
120 PMOS transistor
122 NMOS transistor
124 PMOS transistor
126 NMOS transistor
128 PMOS transistor
130 NMOS transistor
150 table

What is claimed is:

1. A digital logic level shifter, comprising:
an initial stage including a conventional 4-terminal bridge-type inverter circuit;
a middle stage including a 5-terminal first logic reversing circuit that has two middle stage inputs that are not connected in common; and
a final stage including a 5-terminal second logic reversing circuit that has two final stage inputs that are not connected in common.

2. The shifter of claim 1 in which the shifter has an input terminal, an output terminal, a ground terminal, a first voltage terminal, and a second voltage terminal, wherein:
said initial stage has an inverter ground connected to the ground terminal, an inverter supply connected to the first voltage terminal, an inverter input, and an inverter output;
said middle stage has a middle stage ground connected to the ground terminal, a middle stage supply connected to the second voltage terminal, a first middle stage input, a second middle stage input, and a middle stage output;
said final stage has a final stage ground connected to said ground terminal, a final stage supply connected to the second voltage terminal, a first final stage input, a second final stage input, and a final stage output; and wherein
said inverter input is connected to the input terminal, said inverter output is connected to said second final stage input, said first middle stage input is connected to the output terminal, said second middle stage input is connected to the input terminal, said middle stage output is connected to said first final stage input, and said final stage output is connected to the output terminal.

3. The shifter of claim 1, wherein said first logic reversing circuit includes a complimentary pair of transistors.

4. The shifter of claim 3, wherein said transistors are field effect type transistors.

5. The shifter of claim 4, wherein said transistors are a p-channel metal-oxide semiconductor and an n-channel metal-oxide semiconductor.

6. The shifter of claim 1, wherein said second logic reversing circuit includes a complimentary pair of transistors.

7. The shifter of claim 6, wherein said transistors are field effect type transistors.

8. The shifter of claim 7, wherein said transistors are a p-channel metal-oxide semiconductor and an n-channel metal-oxide semiconductor.

9. A method for performing a voltage level shift on a digital input signal having logic states represented by a ground voltage level or a first voltage level, to produce a digital output signal having logic states represented by the ground voltage level or a second voltage level, the method comprising:
(a) inverting the input signal into an initial stage output having opposite logic state represented by either the ground voltage level or the first voltage level;
(b) receiving the input signal and the output signal into a middle stage, wherein the input signal and the output signal have corresponding logic states, and producing a middle stage output having opposite logic state represented by either the ground voltage level or the second voltage level; and
(c) receiving said middle stage output and said initial stage output into a final stage, wherein said middle stage output and said initial stage output have corresponding logic states, and producing the output signal having opposite logic state represented by either the ground voltage level or the second voltage level.

10. The method of claim 9, wherein said (a) is performed using a conventional 4-terminal bridge-type inverter circuit.

11. The method of claim 9, wherein said (b) and said (c) are performed using 5-terminal logic reversing circuits.

12. The method of claim 11, wherein said 5-terminal second logic reversing circuits each include a complimentary pair of transistors.

13. The method of claim 12, wherein said complimentary pair of transistors are field effect type transistors.

14. The method of claim 13, wherein said complimentary pair of transistors include a p-channel metal-oxide semiconductor and an n-channel metal-oxide semiconductor.

15. A system for performing a voltage level shift on a digital input signal having logic states represented by a ground voltage level or a first voltage level to produce a digital output signal having logic states represented by the ground voltage level or a second voltage level, comprising:
means for inverting the input signal into an initial stage output having opposite logic state represented by either the ground voltage level or the first voltage level;
middle stage means for receiving the input signal and the output signal, wherein the input signal and the output signal have corresponding logic states, and for producing a middle stage output having opposite logic state represented by either the ground voltage level or the second voltage level; and
final stage means for receiving said middle stage output and said initial stage output, wherein said middle stage output and said initial stage output have corresponding logic states, and for producing the output signal having opposite logic state represented by either the ground voltage level or the second voltage level.

16. The system of claim 15, wherein said means for inverting includes a conventional 4-terminal bridge-type inverter circuit.

17. The system of claim 15, wherein said middle stage means each include a 5-terminal logic reversing circuit.

18. The system of claim 17, wherein said 5-terminal second logic reversing circuits each include a complimentary pair of transistors.

19. The system of claim 18, wherein said complimentary pair of transistors are field effect type transistors.

20. The system of claim 19, wherein said complimentary pair of transistors include a p-channel metal-oxide semiconductor and an n-channel metal-oxide semiconductor.
